(19) United States
(12) Patent Application Publication
(10) Pub. No.: US 2024/0379603 A1
(43) Pub. Date: Nov. 14, 2024

(54) STRUCTURE AND METHOD FOR POWER METAL LINES

(71) Applicant: SEMICONDUCTOR COMPONENTS INDUSTRIES, LLC, Scottsdale, AZ (US)

(72) Inventor: Eiji KUROSE, Chuo-city (JP)

(73) Assignee: SEMICONDUCTOR COMPONENTS INDUSTRIES, LLC, Scottsdale, AZ (US)

(21) Appl. No.: 18/313,425

(22) Filed: May 8, 2023

(51) Int. Cl. H01L 23/00

(52) U.S. Cl. CPC H01L 24/13; H01L 24/03; H01L 24/05; H01L 24/11; H01L 2224/03; H01L 2224/05147; H01L 2224/05624; H01L 2224/05647; H01L 2224/05666; H01L 2224/05681; H01L 2224/05684; H01L 2224/11464; H01L 2224/13147; H01L 2224/13582; H01L 2224/13611; H01L 2224/13639; H01L 2224/13644; H01L 2224/13655; H01L 2224/13664

(57) ABSTRACT

A semiconductor device component includes a contact pad disposed on a surface of a semiconductor substrate, a seed metal layer disposed on the contact pad, and an interconnect disposed on the seed metal layer. The seed metal layer has a width that is greater than the width of the interconnect with a footer portion of the seed metal layer extending outside the width of the interconnect. The semiconductor device component further includes an etch-resistant protective structure disposed on surfaces of the interconnect and the footer portion of the seed metal layer extending outside the width of the interconnect.

### TECHNICAL FIELD

This description relates in general to semiconductor components and, more particularly, to metallization systems in semiconductor components.

### BACKGROUND

A metallization layer (e.g., a redistribution layer (RDL) on an integrated circuit chip includes the electrical conductors (wires) that connect the transistors and other components on the chip. Aluminum and copper are two common metals that are commonly used for metallization of integrated circuits. As circuit dimensions decrease below the 0.25 μm level, copper is beginning to replace aluminum as a primary metallization medium.

### SUMMARY

In a general aspect, a semiconductor device component includes a contact pad disposed on a surface of a semiconductor substrate, a seed metal layer disposed on the contact pad, and an interconnect disposed on the seed metal layer. The seed metal layer has a width that is greater than a width of the interconnect with a footer portion of the seed metal layer extending outside the width of the interconnect. The semiconductor device component further includes an etch-resistant protective structure disposed on surfaces of the interconnect and the footer portion of the seed metal layer extending outside the width of the interconnect.

In a general aspect, a semiconductor device component includes a contact pad disposed on a surface of a semiconductor substrate, a metal line made of copper, and a seed metal layer interposed between the contact pad and the metal line. The seed metal layer has a width that is greater than a width of the metal line with a footer portion of the seed metal layer extending from underneath the metal line to a side of the metal line. The semiconductor device component further includes a copper etch-resistant protective structure disposed on a top and the side of the metal line and a top and an edge of the footer portion of the seed metal layer.

In a general aspect, a method includes disposing a contact pad on a surface of a semiconductor substrate, disposing a metal line made of copper on the contact pad, and interposing a seed metal layer between the contact pad and the metal line. The seed metal layer has a width that is greater than a width of the metal line with a footer portion of the seed metal layer extending from underneath the metal line to a side of the metal line. The method further includes disposing an etch-resistant protective structure over the metal line and the footer portion of seed metal layer extending beyond the width of the metal line.

The details of one or more implementations are set forth in the accompanying drawings and the description below. Other features will be apparent from the description and drawings, and from the claims.

### BRIEF DESCRIPTION OF THE DRAWINGS

FIG. 1 illustrates, in a cross-sectional view, an example semiconductor device component in which a protective structure made of copper etch-resistant metals is formed on copper interconnects to protect the copper interconnects from corrosion, in accordance with the principles of the present disclosure.

FIG. 2A illustrates the semiconductor device component of FIG. 1 at a first stage of fabrication.

FIG. 2B illustrates the semiconductor device component of FIG. 1 at a second stage of fabrication.

FIG. 2C illustrates the semiconductor device component of FIG. 1 at a third stage of fabrication.

FIG. 2D illustrates the semiconductor device component of FIG. 1 at a fourth stage of fabrication.

FIG. 2E illustrates the semiconductor device component of FIG. 1 at a fifth stage of fabrication.

FIGS. 2A through 2J illustrate the semiconductor device component of FIG. 1 (e.g., the semiconductor device component of FIG. 1) at various stages of fabrication.

FIG. 2H illustrates the semiconductor device component of FIG. 1 at an eight stage of the fabrication process in which, portions of the seed metal layer (e.g., seed metal layer) on semiconductor substrate that are not masked by spacer (or by copper interconnects) are removed.

FIG. 2I illustrates the semiconductor device component of FIG. 1 at a ninth stage of the fabrication process after removal of the portions of the seed metal layer (e.g., seed metal layer) on silicon substrate that are not masked by spacer (or by copper interconnects).

FIG. 2J illustrates the semiconductor device component of FIG. 1 at tenth stage of the fabrication process after formation of the footer portion (seed metal layer footer).

FIGS. 3A and 3B illustrate additional views of the semiconductor device component of FIG. 1 at different stages of fabrication.

FIG. 4 illustrates an example method for fabricating a copper-based metallization layer (e.g., a redistribution layer) for a semiconductor device component that may include semiconductor devices fabricated in a semiconductor substrate.

FIG. 5 illustrates another example method for fabricating a copper-based metallization layer (e.g., a redistribution layer) for a semiconductor device component.

In the drawings, which are not necessarily drawn to scale, like reference symbols and/or alphanumeric identifiers may indicate like and/or similar components (elements, structures, etc.) in different views. The drawings illustrate, by way of example, but not by way of limitation, various implementations discussed in the present disclosure. Reference symbols and/or alphanumeric identifiers shown in one drawing may not be repeated for the same, and/or similar elements in related views in other drawings. Reference symbols and/or alphanumeric identifiers that are repeated in multiple drawings may not be specifically discussed with respect to each of those drawings but are provided for convenience in cross reference between related views. Also, not all like elements in the drawings are specifically referenced with a reference symbol and/or an alphanumeric identifier when multiple instances of an element are illustrated.

### DETAILED DESCRIPTION

In semiconductor technology, copper interconnects are interconnects (wires, metal lines) made of copper. The copper interconnects can be used, for example, in silicon or other semiconductor integrated circuits (ICs) (semiconductor device component, e.g., a large scale integrated (LSI) chip) to reduce propagation delays and power consumption. Since copper is a better conductor than aluminum (Al). ICs using copper (Cu) for their interconnects can have interconnects with narrower dimensions and have less resistance to passage of electricity through them. These properties of copper interconnects can lead to ICs (semiconductor device components) with better performance. Copper interconnects may be used, for example, for power interconnects to and from an IC chip (e.g., an LSI power chip).

While silicon is the most common semiconductor element used for power semiconductor devices, and while copper is a popular choice for conductor traces on printed circuit boards (PCBs) and ceramic substrates due to its electrical conductivity, diffusion of copper into surrounding materials can degrade the electrical properties of the surrounding materials (e.g., diffused copper atoms form deep-level traps in silicon and therefore adversely affect silicon transistor behavior). Therefore, a barrier metal must be disposed between a copper interconnect and a power semiconductor device to chemically isolate the copper conductor from the silicon below and to limit copper diffusivity into the power semiconductor device.

Because of an inability to plasma etch copper, copper interconnects can be formed, in some example implementations, by a metal patterning process referred to as an additive patterning, also known a damascene process by analogy to a traditional technique of metal inlaying. In this process, an underlying silicon oxide insulating layer is patterned with open trenches or vias where the copper conductor should be. A thick coating of copper that significantly overfills the trenches and vias is deposited on the insulating layer, and chemical-mechanical planarization (CMP) is used to remove the copper that extends above the top of the insulating layer. Copper sunken within the trenches or vias in the insulating layer is not removed and becomes the patterned conductor.

In some other example implementations, copper interconnects can be formed by copper plated on patterned seed metal layers. The metal deposition in a damascene structure can include three steps: copper barrier layer, copper seed metal layer, and bulk copper layer. The first two layers may be made, for example, by sputtering, and the last layer may involve copper electroplating (ECP). The copper barrier layer can, for example, be a tantalum/tantalum-tungsten (Ta/TaW), a titanium/titanium-tungsten (Ti/TiW) or a copper-titanium (Cu/Ti) barrier layer, which prevents copper from diffusing into the dielectric. The copper seed metal layer helps the growth of electroplated bulk copper film. Copper electroplating fills copper in the vias and trenches. After completing copper electroplating, chemical mechanically polishing (CMP) is used to remove excess copper deposited on field areas of the semiconductor device component.

As advanced semiconductor device features shrink with each technology node, interconnect structures made of copper are more important because of the higher electrical conductivity and electro migration resistance of copper. Novel metals are being introduced as barrier materials for advanced technology nodes. These types of materials can enable copper filling of the narrowest structures and act as seed enhancement layers. However, it is difficult to solve the compatibility of the interconnect metals for copper chemical mechanical polishing (CMP) processes. Metal voids (formed due to electromigration) and copper corrosion (due to etching by chemical reactants e.g., acids, alkalis) remain issues that need to be controlled. The wet chemical environment in CMP processes can cause copper corrosion to be one of the major problems of copper interconnects.

Accordingly, it would be advantageous to have a method for protecting copper interconnects on a semiconductor device component from corrosion during and after fabrication.

The disclosure herein describes a method and a structure of a metallization system that protects against electro-migration and corrosion of copper interconnects on a semiconductor device component.

In example implementations of the method, exposed surfaces of a seed metal layer and a copper interconnect (formed on the seed metal layer) that are vulnerable to attack by etchants are in encased in (or coated with) a protective material structure that is resistant to copper etchants (e.g., acids, alkalis).

In example implementations, a semiconductor device component (e.g., a power device component) is fabricated on a semiconductor substrate (e.g., a silicon substrate). A contact pad to a terminal (e.g., an input or output) of a semiconductor device in the semiconductor device component can be a conductive pad (e.g., an aluminum layer) formed on a surface of the silicon substrate. A dielectric passivation layer (e.g., silicon dioxide or silicon nitride) is formed over a portion of aluminum layer and over silicon substrate. A seed metal layer is disposed on the over the dielectric passivation layer and the portion of the conductive pad (i.e., the aluminum layer) that is not protected by the dielectric passivation layer. The seed metal layer may be patterned to define areas for forming the copper interconnects.

A copper interconnect (e.g., a metal line) having a top surface and side surfaces is formed on a patterned portion of the seed metal layer using, for example, an electroplating technique. After the copper interconnect is formed, excess seed metal layer portions (e.g., seed metal layer portions on the dielectric passivation layer) may be removed, for example, by etching. A surface portion and an edge position of the remaining patterned seed metal layer may extend from underneath the copper interconnect to the sides of the copper interconnect and be exposed to the environment. A drawback with this approach is that as the excess seed metal layer portions (e.g., on portions of dielectric passivation layer) are etched away, the seed metal layer portions underneath the copper interconnect may be over etched or undercut forming an undercut region below the copper interconnect. Acids, alkalis, or other contaminants may be trapped in undercut region, which can cause corrosion of the copper interconnect and degrade the reliability of semiconductor component.

In example implementations, a protective structure made of etch-resistant materials (i.e., materials resistant to copper etchants) is disposed on the exposed top and side surfaces of the copper interconnect and on the exposed side surfaces and edges of the patterned seed metal layer underneath the copper interconnect. In example implementations, the protective structure made of copper etch-resistant metals can be formed as an electroless nickel-gold (Ni/Au) protective structure. The Ni/Au protective structure can include a layer of nickel formed on the copper interconnect and a layer of gold formed on the nickel layer. In example implementations, the protective structure extends along the sides of the copper interconnects and also covers the sides (i.e., surface portions and edges) of the portions of the seed metal layer that may extend beyond the copper interconnect.

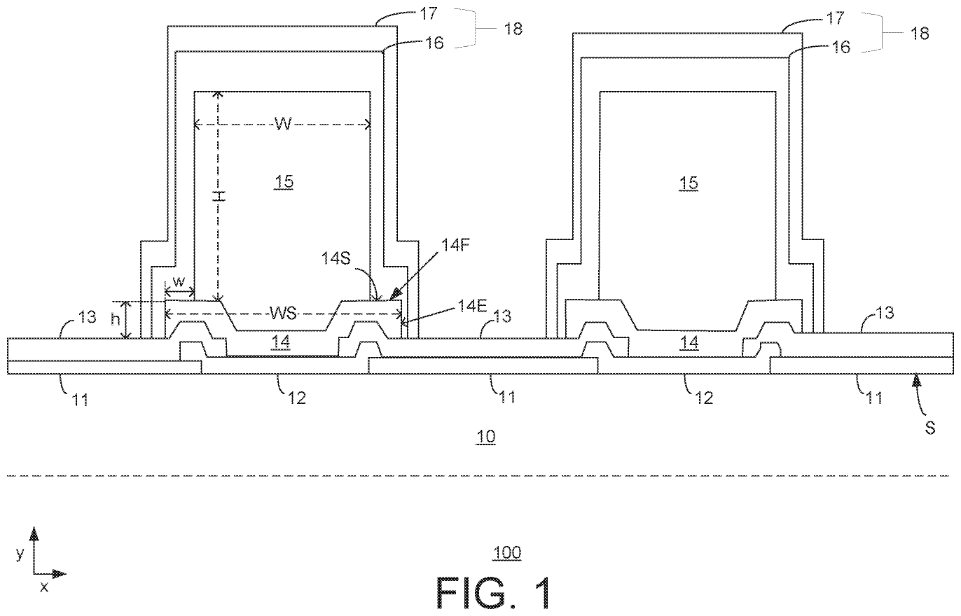

FIG. 1 shows, in a cross-sectional view, an example semiconductor device component 100 in which a protective structure 18 made of etch-resistant metals is formed on copper interconnects 15 to protect the copper interconnects from corrosion, in accordance with the principles of the present disclosure.

The protective structure may be made, for example, of an electroless Ni/Au bilayer deposited on the exposed top and side surfaces of copper interconnects and on the exposed side surfaces and edges of patterned portions of seed metal layers on which the copper interconnects are formed.

As shown in FIG. 1, semiconductor device component 100 may include semiconductor devices (e.g., power devices) (not shown) formed in a semiconductor substrate (e.g., a silicon substrate 10). Aluminum contact pads 12 are disposed in a layer of oxide 11 on a surface S of silicon substrate 10. Aluminum contact pads 12 may be connected to terminals of the semiconductor devices (not shown) formed in silicon substrate 10. A layer of passivating material 13 (e.g., silicon dioxide, or silicon nitride) may be disposed on layer of oxide 12 and aluminum contact pads 12. A seed metal layer 14 may be disposed on the layer of passivating material 13 and the aluminum contact pads 12. Further, the copper interconnects 15 may be formed on the seed metal layer 14 that is in contact with aluminum contact pads 12. A copper interconnect 15 (e.g., a metal line) may, for example, have a rectangular cross section with a width W (e.g., in an x direction) and height H (e.g., in an y direction) above a top surface 14S of seed metal layer 14. In example implementations, copper interconnect 15 may be a power metal line. An example power metal line may have width W and height H dimensions of several microns each. In an example implementation, width W may be in a range of 5 μm to 30 μm (e.g., 20 μm), and height H may be in a range of 5 μm to 20 μm (e.g., 10 μm).

During fabrication of semiconductor device component 100, seed metal layer 14 may be patterned and etched so that a remaining portion of seed metal layer underneath copper interconnect 15 has a width WS that is the same as or larger than the width W of copper interconnect 15. In the example shown FIG. 1, the remaining portion of seed metal layer (after etching) has a further portion (e.g., seed metal layer footer 14F) that extends beyond the width W of copper interconnect 15. The portion of seed metal layer 14 extending beyond the width W of copper interconnect 15 (e.g., seed metal layer footer 14F) may, for example, have a top surface 14S with a width w in the x direction and an edge 14E (e.g., a vertical edge) with a height h in the y direction.

To protect the copper in copper interconnect 15 from corrosion, a protective structure 18 is disposed on the top surface and side surfaces of copper interconnect 15. Protective structure 18 also extends further down along the sides of copper interconnect 15 in the −y direction (e.g., up to passivation layer 13) to encase (or coat) the portion of seed metal layer 14 (e.g., seed metal layer footer 14F) that extends beyond the width W of copper interconnect 15. Protective structure 18 may coat all surfaces of seed metal layer footer 14F including edge 14E (having a height h in the −y direction). Protective structure 18 may seal all portions of seed metal layer footer 14F that extend beyond the width W of copper interconnect 15 and protect seed metal layer footer 14F from etchants.

In example implementations, protective structure 18 may include a bilayer of nickel (e.g., layer 16) and gold (e.g., layer 17). The bilayer of nickel and gold may be formed by electroless deposition of nickel followed by electroless deposition of gold. In some example implementations, protective structure 18 may include a layer of nickel (e.g., layer 16) and a layer of another chemically inert metal or alloy (e.g., palladium or a tin-silver alloy) (e.g., layer 17) that is chemically resistant to copper etchants.

Protective structure 18 may seal seed metal layer footer 14F and block side or undercut etching (i.e., etching along the x direction) of seed metal layer footer 14F by wet etchants that may be present outside seed metal layer footer 14F, for example, in later CMP processes.

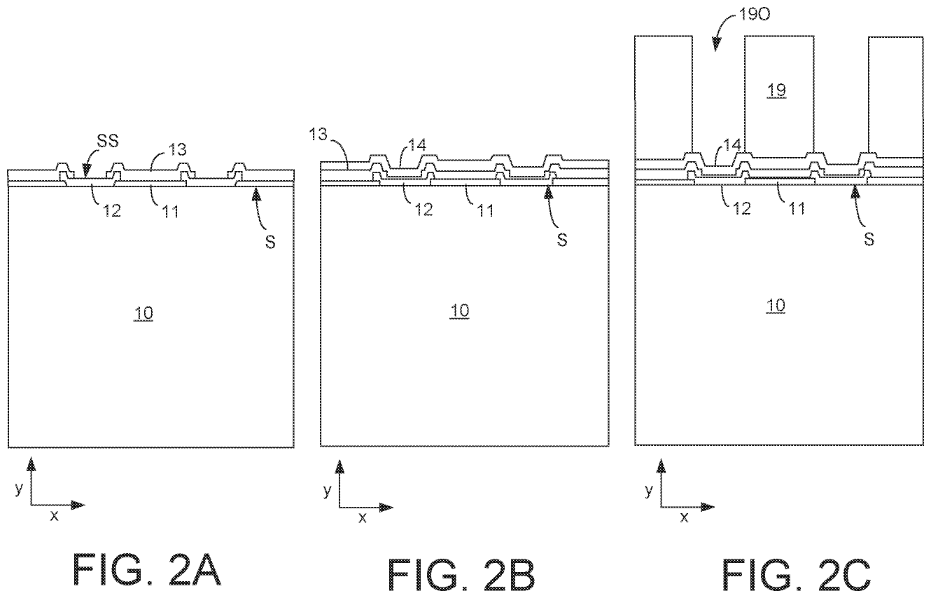

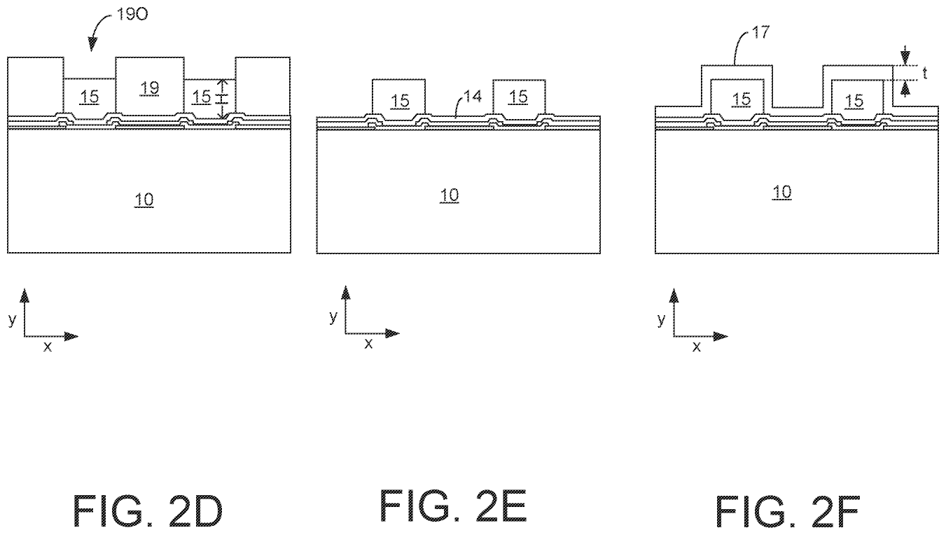

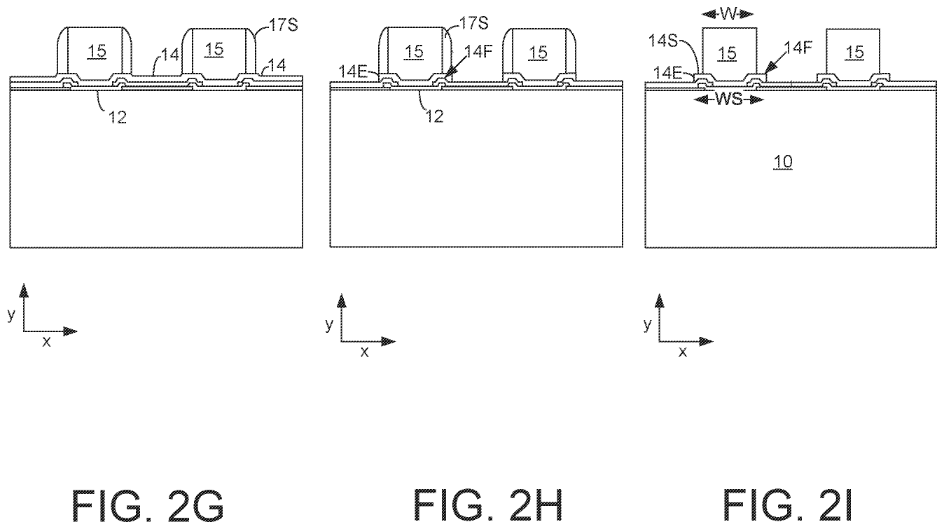

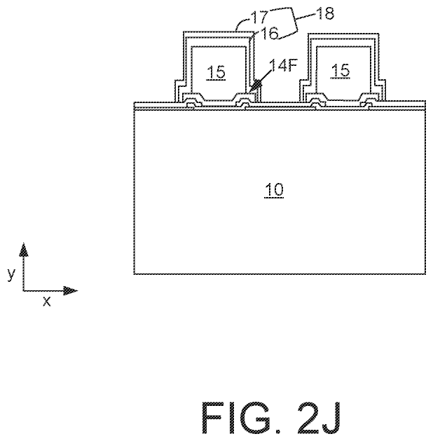

FIGS. 2A through 2J illustrate the semiconductor device component of FIG. 1 (e.g., semiconductor device component 100) at various stages of fabrication.

FIG. 2A shows semiconductor device component 100 at a first stage of fabrication. At this first stage, conductive contact pads are formed on a top surface S of a semiconductor substrate (e.g., a silicon substrate 10). The conductive contact pads (e.g., aluminum contact pads 12) may be formed in a layer of oxide 11 (e.g., surface oxide) on the top surface S of the silicon substrate. The conductive pads (e.g., aluminum contact pads 12) may be connected to terminals of the semiconductor devices (not shown) formed in silicon substrate 10.

Further, a passivation layer (e.g., passivation layer 13) may be disposed on layer of oxide 11 (e.g., surface oxide) on the top surface S of the semiconductor substrate. Passivation layer 13 may, for example, include silicon oxide, silicon nitride, or other dielectric material, etc. Passivation layer 13 may be lithographically patterned and etched to expose top surfaces SS of the conductive contact pads (e.g., aluminum contact pads 12) through openings in passivation layer 13.

FIG. 2B shows semiconductor device component 100 at a second stage of fabrication. At this second stage, a seed metal layer (e.g., seed metal layer 14) may be disposed on passivation layer 13 and the top surfaces SS of the conductive pads (e.g., aluminum contact pads 12). The seed metal layer (e.g., seed metal layer 14) may include barrier materials (e.g., tantalum (Ta), tantalum-tungsten (TW), titanium (Ti), titanium-tungsten (TiW), etc.) and include a metallic seeding material layer such as a copper layer. Seed metal layer 14 (including, e.g., TiW and copper) may, for example, be sputter deposited on silicon substrate 10. In some example implementations, seed metal layer 14 may include a Ti or TiW layer having a thickness of about 750 Å to about 1500 Å, and a copper layer having a thickness of about 1500 Å to about 5000 Å.

FIG. 2C shows semiconductor device component 100 at a third stage of fabrication. At this third stage, a lithographically patterned resist layer 19 may be disposed on the semiconductor substrate (e.g., a silicon substrate 10) on a top of the seed metal layer (e.g., seed metal layer 14). The lithographically patterned resist layer 19 may include openings 19O aligned with the conductive contact pads (e.g., aluminum contact pads 12) disposed on the top surface S of the semiconductor substrate. Openings 19O may correspond to a layout of interconnects for a redistribution layer (RDL) of semiconductor device component 100 that are formed in further stages of the fabrication.

FIG. 2D shows semiconductor device component 100 at a fourth stage of fabrication. At this fourth stage, copper metal may be disposed in openings 19O in the lithographically patterned resist layer 19 to form the copper interconnects (e.g., copper interconnects 15) of semiconductor device component 100. In example implementations, the copper disposed in openings 19O may have a thickness or height H (e.g., in the y direction) of about 5 μm to 20 μm (e.g., 10 μm). In example implementations, the copper disposed in openings 19O may be electroplated on seed metal layer 14 in the openings.

FIG. 2E shows semiconductor device component 100 at a fifth stage of fabrication. At this fifth stage, the resist layer (e.g., lithographically patterned resist layer 19) is removed leaving copper interconnects 15 disposed on the seed metal layer (e.g., seed metal layer 14) on the top surface S of the semiconductor substrate.

Further stages of fabrication may involve masking and etching of the seed metal layer (e.g., seed metal layer 14) to remove the seed metal layer from most of the top surface S of the silicon substrate 10 on the sides of copper interconnects 15 while leaving a portion of the seed metal layer (e.g., seed metal layer footer 14F) that extends beyond the width W of copper interconnect 15 (FIG. 1). This masking and etching of the seed metal layer (e.g., seed metal layer 14) may involve photoresist masks or tetraethoxysilane (TEOS) masks to make spacers adjacent (or along) the vertical sides of copper interconnect 15.

FIGS. 2F and 2G illustrate an example use of a TEOS spacer (e.g., spacer 17S) for patterned removal (etching) of the seed metal layer (e.g., seed metal layer 14) on semiconductor device component 100. As shown in FIG. 2F, at a sixth stage of fabrication, a conformal layer of TEOS (e.g., TEOS layer 17) of thickness t may be deposited (e.g., by chemical vapor deposition (CVD)) on the silicon substrate 10. In example implementations thickness t of TEOS layer 17 may for example be in a range of 2 μm to 7 μm (e.g., 5 μm). TEOS layer 17 may conformally extend over the top and the sides of copper interconnects 15 and the seed metal layer (e.g., seed metal layer 14) on silicon substrate 10.

As shown in FIG. 2G, at a seventh stage of fabrication, the conformal TEOS layer 17 may be etched back directionally (e.g., by an anisotropic dry etch) through the thickness t (in the minus y direction) to clear TEOS material disposed on the top of copper interconnects 15 and the top of the seed metal layer 14. The anisotropic dry etch may leave behind TEOS (or resist material) forming spacer 17S adjacent to or along sides of copper interconnects 15.

In some other example implementations, instead of using CVD TEOS material, spacer 17S may be formed of photoresist material that is spin coated or spray coated on silicon substrate 10.

FIG. 2H shows semiconductor device component 100 at an eight stage of the fabrication process in which, portions of the seed metal layer (e.g., seed metal layer 14) on semiconductor substrate 10 that are not masked by spacer 17S (or by copper interconnects 15) are removed. The removal of the seed metal layer may include etching of all constituents of the seed metal layer (e.g., copper and barrier materials such as Ti or TiW).

FIG. 2I shows semiconductor device component 100 at a ninth stage of the fabrication process. At this ninth stage, spacer 17S (TEOS or resist) is removed leaving in place a portion of the seed metal layer underneath copper interconnect 15 having a width WS wider than the width W of copper interconnect 15. The portion of the seed metal layer extending beyond the width W of copper interconnect 15 may include a footer portion (seed metal layer footer 14F) with a vertical edge 14E and a surface 14S extending to a side of copper interconnect 15.

FIG. 2J shows semiconductor device component 100 at tenth stage of the fabrication process after formation of the footer portion (seed metal layer footer 14F). At this stage, a protective structure (e.g., protective structure 18) is disposed on the top and the sides of copper interconnect 15. Protective structure 18 further encapsulates the footer portion (seed metal layer footer 14F) of the seed metal layer underneath the copper interconnect extending beyond the width of copper interconnect 15.

Protective structure 18 may include copper etch-resistant materials (e.g., Ni, palladium (Pd), Au, tin-silver (Sn—Ag) alloy, etc.). In example implementations, protective structure may include a bilayer of nickel (e.g., layer 16) and gold (e.g., layer 17). In example implementations, the layer of nickel (e.g., layer 16) may have a thickness for example, in a range of 1 μm to 4 μm (e.g., 2 μm). The layer of gold (e.g., layer 17) may have a thickness, for example, of 1 μm or less (e.g., 0.25-0.5 μm).

Protective structure 18 may enclose or encase seed metal layer footer 14F (including edge 14E and surface 14S). Protective structure 18 may seal edge 14E and surface 14S of seed metal layer footer 14F to prevent etchants (e.g., a wet acid etchant) from attacking seed metal layer footer 14F and thereby avoid undercutting of the seed metal layer. This blocking of potential undercutting of the seed metal layer may prevent etchants from further reaching and corroding copper interconnect 15.

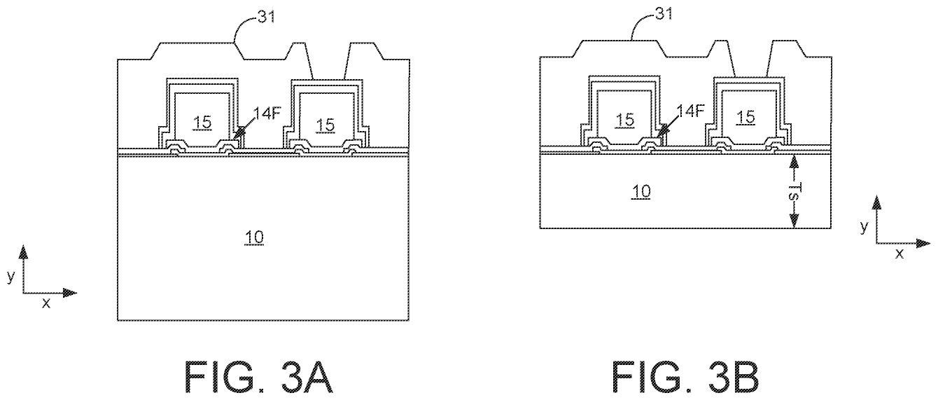

In example implementations, as shown in FIG. 3A, at a further stage of the fabrication process, a layer of epoxy (e.g., resin 31) may be disposed on semiconductor device component 100 encasing the redistribution layer components (e.g., copper interconnects 15) formed on the top surface of silicon substrate 10. Further, in some example implementations, as shown in FIG. 3B, at a next stage in the fabrication process, semiconductor device component 100 may reduce a thickness of the silicon substrate 10 (e.g., to a thickness Ts) by back grinding the substrate.

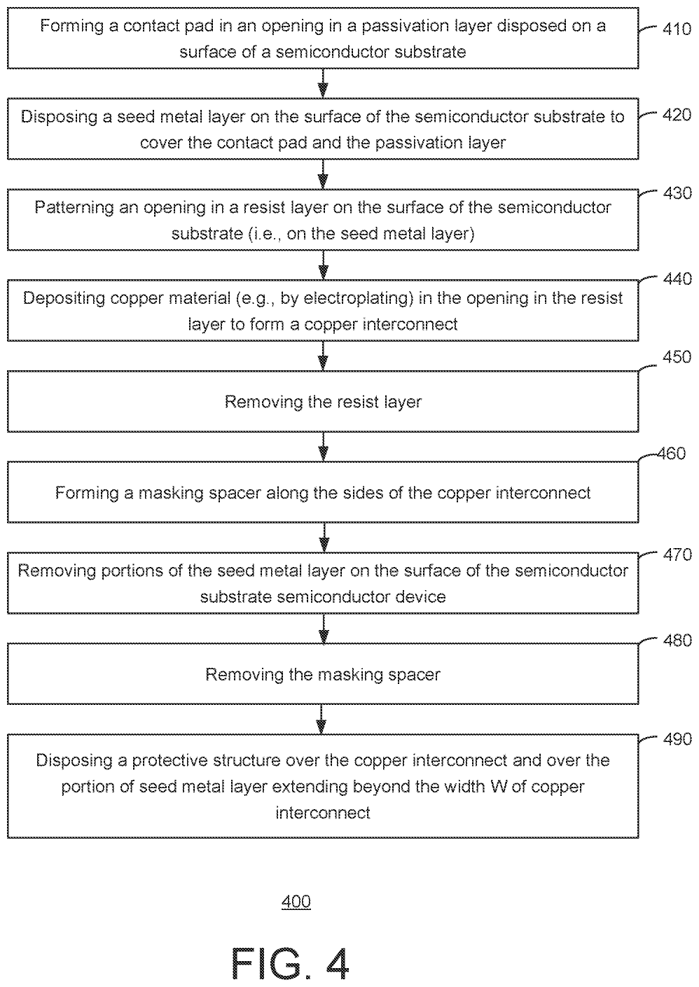

FIG. 4 shows an example method 400 for fabricating a copper-based metallization layer (e.g., a redistribution layer) for a semiconductor device component that may include semiconductor devices fabricated in a semiconductor substrate.

Method 400 includes forming a contact pad in an opening in a passivation layer disposed on the surface of the semiconductor substrate (410). The contact pad may be made of conductive material (e.g., aluminum, copper, aluminum-copper alloy, etc.) and may be connected to the semiconductor devices formed in the semiconductor substrate. The contact pads may be exposed through the opening in the passivation layer disposed on the surface of the semiconductor substrate. The passivation layer may be made of silicon oxide, silicon nitride, or other dielectric material.

Method 400 further includes disposing a seed metal layer on the surface of the semiconductor substrate to cover the contact pad and the passivation layer (420). The seed metal layer may include copper and barrier layer materials (e.g., Ti, TiW, Ta, TaW, etc.). In some example implementations, disposing the seed metal layer may include sputtering a TiCu or TiWCu film on the surface of the semiconductor substrate.

Method 400 may further include patterning an opening in a resist layer on the surface of the semiconductor substrate (i.e., on the seed metal layer) (430). The patterned resist layer may have several openings corresponding to a layout of interconnects for a copper-based metallization layer. An opening having a width W in the resist layer may, for example, be aligned with the contact pad on the surface of the semiconductor substrate.

Method 400 may further include depositing copper material (e.g., by electroplating) in the opening in the resist layer (440). In example implementations, the copper may be deposited in the opening aligned with the contact pad on the surface of the semiconductor substrate. The copper that is deposited in the opening in the resist layer will be in contact with the seed metal layer covering the contact pad and form a copper interconnect of a semiconductor device component. The copper interconnect deposited in the opening may have a height H and a width W.

Method 400 may further include removing the resist layer (450) and forming a masking spacer along the sides of the copper interconnect (460). In example implementations, forming a masking spacer along the sides of the copper interconnect may include coating the semiconductor substrate (including the top and the sides of the copper interconnect, and the top surface of the seed metal layer) with a conformal layer of a masking material. In example implementations, the masking material may be CVD TEOS material or a spin-coated or spray-coated resist material. Forming the masking spacer along the sides of the copper interconnect may further include anisotropic etch back of the conformal layer of the masking material to clear the masking material on top of the copper interconnect and on the top surface of the seed metal layer. The anisotropic etch back may form the masking spacer adjacent (attached) to (vertical) sides of the copper interconnect.

Method 400 further includes removing portions of the seed metal layer on the surface of the semiconductor substrate semiconductor device (470). Removing portions of the seed metal layer may involve etching portions of the seed metal layer that are not masked by the masking spacer (or the copper interconnect). The etching may involve etchants based on the constituents of the seed metal layer (e.g., Cu, Ti, TiW, Ta or TaW, etc.). As a result of etching outside the masking spacer, a remainder (unetched) portion of the seed metal layer (underneath the masking spacer and the copper interconnect) may extend beyond the width W of copper interconnect 15 (FIGS. 2H and 2I). The portion of seed metal layer 14 extending beyond the width W of copper interconnect 15 (e.g., seed metal layer footer 14F) may, for example, have a top surface 14S with a width w in the x direction and an edge 14E (e.g., a vertical edge) with a height h in the y direction (FIGS. 2H and 2I). In example implementations, the width w of seed metal layer footer 14F in the x direction may be in a range of 0 μm to 10 μm (e.g., 5 μm).

Method 400 further includes removing the masking spacer (480) (made of TEOS or resist material), and disposing a protective structure over the copper interconnect and over the portion of seed metal layer extending beyond the width W of copper interconnect (490). The protective structure may include materials (e.g., Ni, Au, Pd, Sn—Ag alloy, etc.) that are generally resistant to wet etching by acids or alkalis. In example implementations, the protective structure may include a Ni layer and an Au layer. The Ni layer and the Au layer may be deposited by electroless plating on all copper bearing surfaces (e.g., the top and side surfaces of the copper interconnect, and the top surface and edge of the portion of seed metal layer extending beyond the width W of copper interconnect. The protective structure is disposed to seal all copper-bearing surfaces of the copper interconnect and seed metal layer from access by etchants.

In some example implementations, method 400 may further include disposing an epoxy or resin (e.g., a polyimide, polybenzoxazoles (PBO) polymer, phenols, etc.) on the semiconductor device component encasing the redistribution layer components (e.g., copper interconnects) formed on the top surface of silicon substrate (FIG. 3A). Further, in some example implementations, method 400 may further include back grinding the semiconductor device component to reduce a thickness of the silicon substrate (e.g., to a thickness Ts) (FIG. 3B).

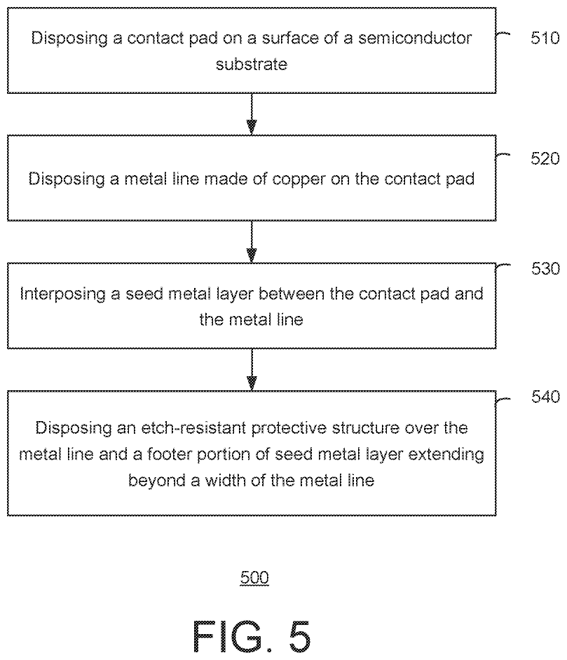

FIG. 5 shows another example method 500 for fabricating a copper-based metallization layer (e.g., a redistribution layer) for a semiconductor device component that may include semiconductor devices fabricated in a semiconductor substrate.

Method 500 includes disposing a contact pad on a surface of a semiconductor substrate (510), disposing a metal line made of copper on the contact pad (520), and interposing a seed metal layer between the contact pad and the metal line (530). The seed metal layer has a width that is greater than a width of the metal line with a footer portion of the seed metal layer extending from underneath the metal line to a side of the metal line.

Method 500 further includes disposing an etch-resistant protective structure over the metal line and the footer portion of seed metal layer extending beyond a width of the metal line (540).

In method 500, interposing the seed metal layer between the contact pad and the metal line includes disposing a precursor seed metal layer on the surface of the semiconductor substrate including above the contact pad, disposing the metal line made of copper on the precursor seed metal layer above the contact pad, forming a masking spacer along a side of the metal line to mask a portion of the precursor seed metal layer disposed on the surface of the semiconductor substrate, and etching an unmasked portion of the precursor seed metal layer to form the seed metal layer interposed between the contact pad and the metal line with the footer portion of the seed metal layer extending from underneath the metal line to the side of the metal line.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device component comprising:
a contact pad disposed on a surface of a semiconductor substrate;
a seed metal layer disposed on the contact pad;
an interconnect disposed on the seed metal layer, the seed metal layer having a width that is greater than a width of the interconnect with a footer portion of the seed metal layer extending outside the width of the interconnect; and
an etch-resistant protective structure disposed on surfaces of the interconnect and the footer portion of the seed metal layer extending outside the width of the interconnect.

2. The semiconductor device component of claim 1, wherein the interconnect is made of copper and the contact pad includes aluminum or an aluminum-copper alloy.

3. The semiconductor device component of claim 1, wherein the seed metal layer include a barrier metal layer made of at least one of titanium (Ti), titanium-tungsten (TiW), tantalum (Ta), and tantalum-tungsten (TaW).

4. The semiconductor device component of claim 3, wherein the seed metal layer includes a copper layer.

5. The semiconductor device component of claim 4, wherein the seed metal layer includes a Ti or TiW layer having a thickness of about 750 Å to about 1500 Å, and a copper layer having a thickness of about 1500 Å to about 5000 Å.

6. The semiconductor device component of claim 1, wherein the interconnect includes copper material electroplated on the seed metal layer.

7. The semiconductor device component of claim 1, wherein the seed metal layer includes material sputtered on the contact pad.

8. The semiconductor device component of claim 1, wherein the etch-resistant protective structure disposed on surfaces of the interconnect and the footer portion of the seed metal layer extending outside the width of the interconnect includes materials that are resistant to copper etchants.

9. The semiconductor device component of claim 1, wherein the etch-resistant protective structure disposed on surfaces of the interconnect and the footer portion of the seed metal layer extending outside the width of the interconnect includes at least one of nickel, palladium, gold, and a tin-silver alloy.

10. The semiconductor device component of claim 1, wherein the etch-resistant protective structure disposed on surfaces of the interconnect and the footer portion of the seed metal layer extending outside the width of the interconnect includes a layer of nickel and a layer of gold.

11. The semiconductor device component of claim 1, wherein the etch-resistant protective structure disposed on surfaces of the interconnect and the footer portion of the seed metal layer extending outside the width of the interconnect seals an edge and a surface of the footer portion of the seed metal layer extending outside the width of the interconnect.

12. A semiconductor device component comprising:
a contact pad disposed on a surface of a semiconductor substrate;
a metal line made of copper;
a seed metal layer interposed between the contact pad and the metal line, the seed metal layer having a width that is greater than a width of the metal line with a footer portion of the seed metal layer extending from underneath the metal line to a side of the metal line; and
a copper etch-resistant protective structure disposed on a top and the side of the metal line and a top and an edge of the footer portion of the seed metal layer.

13. The semiconductor device component of claim 12, wherein the seed metal layer includes copper and at least one of tantalum (Ta), tantalum-tungsten (TW), titanium (Ti), titanium-tungsten (TiW).

14. The semiconductor device component of claim 12, wherein the copper etch-resistant protective structure includes at least one of nickel, gold, palladium, and a tin-silver alloy.

15. A method comprising:
disposing a contact pad on a surface of a semiconductor substrate;
disposing a metal line made of copper on the contact pad;
interposing a seed metal layer between the contact pad and the metal line, the seed metal layer having a width that is greater than a width of the metal line with a footer portion of the seed metal layer extending from underneath the metal line to a side of the metal line; and
disposing an etch-resistant protective structure over the metal line and the footer portion of seed metal layer extending beyond the width of the metal line.

16. The method of claim 15, wherein interposing the seed metal layer between the contact pad and the metal line includes:
disposing a precursor seed metal layer on the surface of the semiconductor substrate including above the contact pad;
disposing the metal line made of copper on the precursor seed metal layer above the contact pad;
forming a masking spacer along a side of the metal line to mask a portion of the precursor seed metal layer disposed on the surface of the semiconductor substrate; and
etching an unmasked portion of the precursor seed metal layer to form the seed metal layer interposed between the contact pad and the metal line with the footer portion of the seed metal layer extending from underneath the metal line to the side of the metal line.

17. The method of claim 15, wherein a width W of the metal line is in a range of 5 μm to 30 μm and a height H of the metal line is in a range of 5 μm to 20 μm.

18. The method of claim 15, wherein disposing an etch-resistant protective structure includes disposing a layer of nickel and a layer of one of gold, palladium or a tin-silver alloy over the metal line and the footer portion of seed metal layer.

19. The method of claim 18, wherein disposing the layer of nickel and the layer of one of gold, palladium or a tin-silver alloy includes electroless deposition of the layer of nickel and electroless deposition of the layer of one of gold, palladium, or a tin-silver alloy.

20. The method of claim 15, wherein the seed metal layer includes copper and at least one of tantalum (Ta), tantalum-tungsten (TW), titanium (Ti), titanium-tungsten (TiW) that are sputter deposited on the semiconductor substrate.

21. The method of claim 15, wherein the seed metal layer includes a Ti or TiW layer having a thickness in a range of 750 Å to 1500 Å, and a copper layer having a thickness of in a range of 1500 Å to 5000 Å.
